(19) United States
(12) Patent Application Publication
(10) Pub. No.: US 2024/0201416 A1
(43) Pub. Date: Jun. 20, 2024

(54) METHOD AND SYSTEM FOR DETERMINING HYDROLOGIC CONDITIONS ASSOCIATED WITH A SURFACE POINT

(71) Applicant: Aquanty Inc., Waterloo (CA)

(72) Inventors: Steven K. FREY, Waterloo (CA); Graham STONEBRIDGE, Waterloo (CA); Derek STEINMOELLER, Waterloo (CA); Andre ERLER, Waterloo (CA); Najmi SHAMALISHAM, Waterloo (CA); Amanda TAYLOR, Waterloo (CA); Steven BERG, Waterloo (CA); Edward SUDICKY, Waterloo (CA)

(21) Appl. No.: 18/287,059

(22) PCT Filed: Apr. 22, 2022
(86) PCT No.: PCT/CA2022/050616

§ 371 Date: Oct. 16, 2023

Related U.S. Application Data
(60) Provisional application No. 63/178,200, filed on Apr. 22, 2021.

(51) Int. Cl. G01V 20/00; G06F 30/28

(52) U.S. Cl. CPC G01V 20/00; G06F 30/28

(57) ABSTRACT

A method and system for determining hydrologic conditions with respect to a surface point including generating one-dimensional columns representing hydrologic properties associated with the surface point to assist in determining the hydrologic conditions. The hydrologic conditions may be associated with historical conditions or a simulation of future conditions of the surface point.

### CROSS-REFERENCE TO OTHER APPLICATIONS

The current disclosure claims priority from U.S. Provisional Application No. 63/178,200 filed Apr. 22, 2021, which is hereby incorporated by reference.

### FIELD

The disclosure is generally directed at the use of technology in the fields of hydrology, hydrogeology, and/or agriculture. More specifically, the disclosure is directed at a method and system for determining hydrologic conditions associated with a surface point.

### BACKGROUND

Fully integrated hydrologic models can be developed for scenario analysis and near-real-time streamflow and groundwater forecasting applications. These models might have spatial coverage up to several thousand square kilometers to assist in predicting soil saturation, groundwater levels and ponded water depth across diverse landscapes over predetermined time periods ranging from hours to weeks to years. Such simulation outputs provide valuable information or data for agricultural decision support systems and for water resources management.

The practicality of large-scale fully integrated hydrologic simulators is limited by the rigidity and computational expense of these models. A typical fully integrated hydrological model may have a spatial resolution limited to 100-1000 m with fixed parameters and will likely not be able to cover or capture all areas of potential interest. The run-time for these hydrologic simulators using currently available high performance computing hardware is on the order of hours. The complexity of these simulators also limits the flexibility required for practical applications requiring near real-time forecasts of hydrologic variables including soil moisture.

From a different perspective, agricultural technology (agtech) decision support systems (DSSs) can recommend field-scale farm management operations based on observations of existing conditions derived from in-situ and spaceborne sensor data. Similar tools exist for forestry and ecosystem goods and services applications, however, these current solutions lack physics-based hydrological simulation capabilities such as the ability to forecast soil moisture at daily or weekly time scales.

The disclosure is directed at a method and system of determining hydrologic conditions associated with a surface point that overcomes at least one disadvantage of current systems.

### SUMMARY

The disclosure is directed at a system and method for determining hydrologic conditions associated with a surface point. In one embodiment, the disclosure uses a one-dimensional (1D) (columnar) environment.

In one aspect of the disclosure, there is provided a method of determining hydrologic conditions associated with a surface point including generating a one-dimensional (1D) mesh based on inputs associated with the surface point; parameterizing the 1D mesh; and generating a parameterized 1D model for use in determining the hydrologic conditions of soil associated with the surface point.

In another aspect, the hydrologic conditions are associated with historical conditions of the soil associated with the surface point or a simulation of future conditions of the soil associated with the surface point. In a further aspect, the method includes performing at least one simulation on the parameterized 1D model to generate simulation results. In yet another aspect, the method further includes transmitting the simulation results to an auxiliary model to generate auxiliary model results. In an aspect, the method further includes transmitting the auxiliary model results to a decisions support system. In yet another aspect, the auxiliary model includes at least one of a crop growth model, a wetland model or an ecosystem goods and services model.

In another aspect, parameterizing the 1D mesh includes processing geospatial data; parameterizing the processed geospatial data; and combining the parameterized processed geospatial data with the 1D mesh. In a further aspect, the method includes processing user inputs; parameterizing the user inputs; and combining the parameterized user inputs with the 1D mesh. In another aspect, the inputs include at least one of geospatial data, near real-time observational data or meteorological data.

In another aspect of the disclosure, there is provided a system for determining hydrology conditions associated with a surface point including an interface for receiving inputs; and a one-dimensional model constructor for processing the inputs and for generating a 1D model presenting hydrology properties associated with the surface point.

In a further aspect, the inputs include geospatial data; near real time observational data; manual user inputs or meteorological data. In another aspect, the system further includes a hydrologic simulator for generating hydrology simulation results based on the 1D model. In yet another aspect, the hydrology simulation results comprise historical conditions of the soil associated with the surface point or a simulation of future conditions of the soil associated with the surface point. In another aspect, the system further includes a set of auxiliary models for generating auxiliary outputs based on the simulation hydrology results. In yet a further aspect, the system includes a decision support service component.

### DESCRIPTION OF THE DRAWINGS

The disclosure will now be described, by way of example only, with reference to the attached Figures.

FIG. 1 is a schematic display of a complete water cycle;

FIG. 2 is a schematic display of use of a one-dimensional column for displaying soil conditions;

FIG. 3 is a schematic diagram of a system for one-dimensional column simulation and forecasting;

FIG. 4 is a schematic diagram of a one-dimensional column mesh;

FIG. 5 is a schematic diagram of a geospatial database querying and column model parameterization;

FIG. 6 is a schematic diagram of inputs to the system for one-dimensional column simulation and forecasting;

FIG. 7 is a flowchart outlining a method of one-dimensional column simulation and forecasting; and

FIG. 8 is a schematic diagram of a process flow of outputs from the system for one-dimensional column simulation and forecasting.

### DETAILED DESCRIPTION

The disclosure is directed at a method and system for determining hydrologic conditions associated with a surface point. In one embodiment, the disclosure is directed at the simulation, near real-time forecasting and/or historical analysis of shallow subsurface hydrology in a fully integrated one-dimensional (1D) setting. In one embodiment, the disclosure includes a method and system for near-real-time simulation and/or historical analysis of shallow subsurface hydrology using 1D columns. In another embodiment, the disclosure is directed at hydrologic properties associated with a surface point.

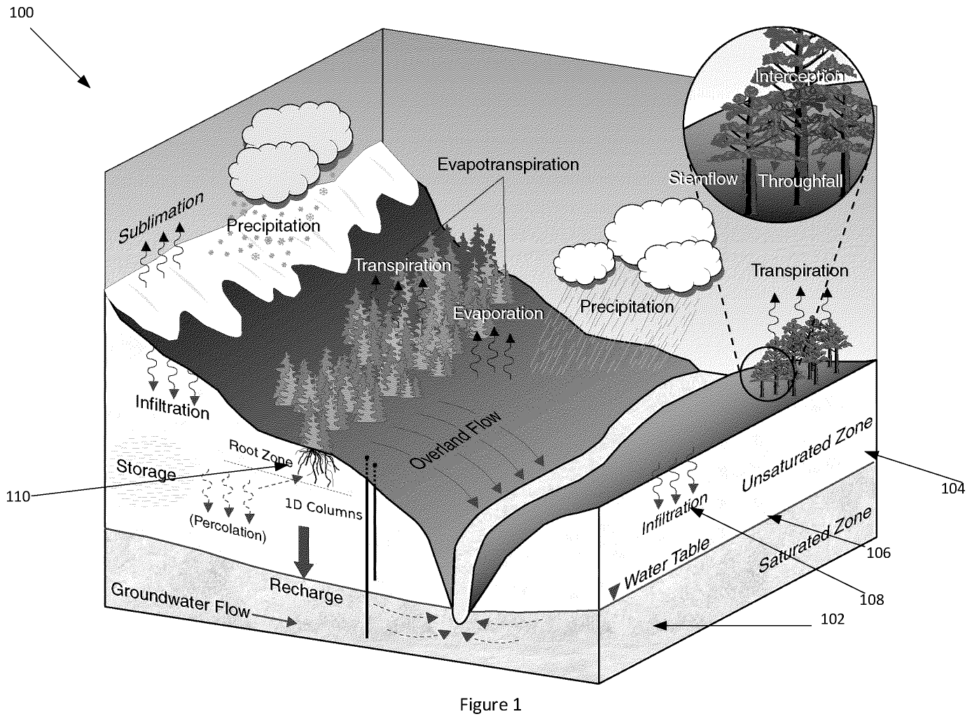

Turning to FIG. 1, a schematic diagram of a water cycle is shown which provides one example or how a water cycle of a selected area may be displayed. The diagram may be generated by a method and/or system for displaying shallow subsurface hydrology. More specifically, FIG. 1 provides one example of how the subsurface hydrology or hydrogeology of the selected area may be displayed by the system and method of the disclosure. The water cycle diagram or representation may provide users (or viewers) with either, or both, historical or forecasting information relating to the subsurface hydrology or hydrogeology of selected area being displayed, such as with respect to a surface point. In one embodiment, this may be facilitated or achieved with 1D hydrostratigraphic columns.

As shown, the diagram includes different surface and subsurface components of the water, or hydrologic, cycle. The representation 100 includes a saturated zone 102 and an unsaturated zone 104 that are present under ground level. As shown in FIG. 1, a water table 106 separates the saturated zone 102 from the unsaturated zone 104. The unsaturated zone 104 may display different areas of where water may travel, such as areas of infiltration 108 where water infiltrates the unsaturated zone 104.

In the current embodiment, the representation 100 includes the display of a root zone 110 which extends down from ground level. Root zones 110 typically extend between one to five meters below ground level, however, the depth to which it extends may be selected to be any depth based on user requirements.

In one embodiment, the disclosure uses one-dimensional (1D) domains or columns that extend vertically downward from a point on the surface (surface point) or ground level to display the root zone 110 or any other areas of interest directly beneath the surface point at ground level. By using 1D columns, or 1D soil columns, the disclosure provides an advantage over current systems in that the representation may be processed and generated in a much faster time frame than current systems. Other aspects or displayed characteristics in the water cycle representation of FIG. 1 will be understood by one skilled in the art.

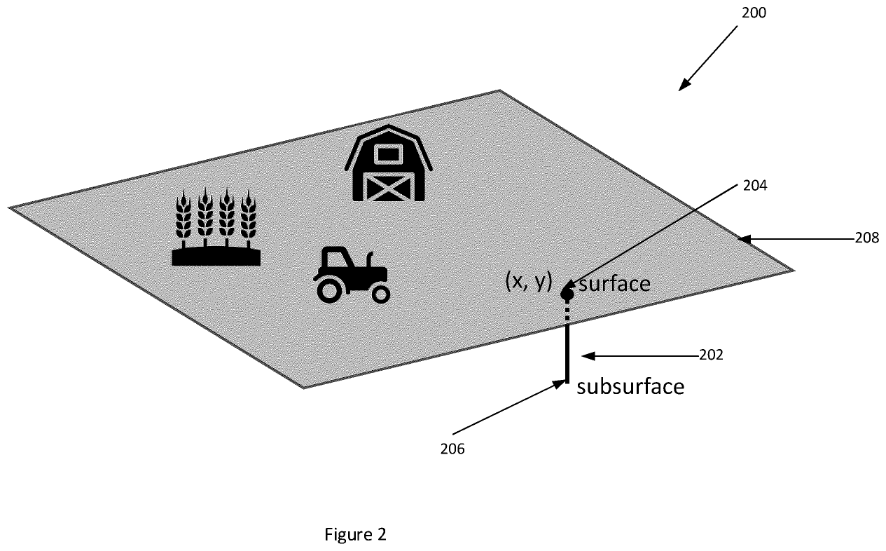

Turning to FIG. 2, a schematic diagram of a one-dimensional soil column in an agricultural setting is shown. The representation 200 of FIG. 2 is a more simplistic drawing or example, however, more details with respect to the use of 1D columns is provided. As shown, the diagram (generated by the system of the disclosure) provides an improved understanding of the soil or land directly underneath a point on the surface (seen as point (x,y)).

In FIG. 2, a soil column 202 extends downwards from a point on the surface, or surface point, 204 towards a point directly underneath the surface point, which may also be referred to as a subsurface point 206. The surface point 204 may be seen as a specific point at ground level 208 while the subsurface point 206 is seen as a specific point below ground level 208 that is directly underneath the surface point 204. As such, the area, distance, or space between the surface point 204 and the subsurface point 206 may be shown or displayed via a 1D column, such as the soil column 202.

As understood, the environment within which the soil column 202 displays information may be agricultural or any other natural landscape. In FIG. 2, the display, or environment, relates to a farm location but the area or landscape of interest that is used may also be the water cycle representation of FIG. 1. In one embodiment, the disclosure provides a method and system to simulate or forecast, future or historical, hydrological state variables such as, but not limited to, soil moisture within, or using, at least one 1D column. The disclosure may also generate historical information with respect to the space, or soil, between the surface point and the subsurface point.

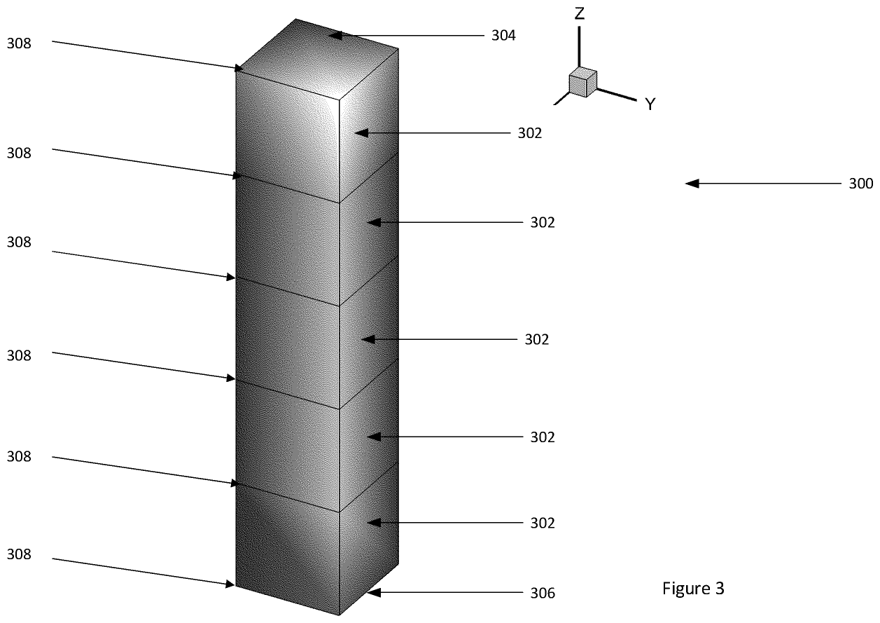

Turning to FIG. 3, a schematic diagram of a 1D column is shown. The 1D column 300 includes a plurality of sections 302, or elements, representing different areas (or depths) between the surface point 304 at and the subsurface point 306 directly underneath the surface point 304. As understood, the 1D column allows the soil under the surface point 304 (such as in the vertical or z-direction) to be discretized into a predetermined number of sections or elements, which in the current diagram is five (5). Based on inputs provided to the system, the 1D column is generated to display hydrologic state variables including, but not limited to, soil moisture and groundwater level at each of the vertices or division lines 308 between different sections 302. In some embodiments, the hydrologic state variables may be predicted by the system or may be displayed directly based on inputs from the user or other external sources. The 1D column display may provide valuable information about water availability or overabundance at different depths beneath the surface point 304 for plant growth and other applications. As discussed above, use of the 1D columns provides an improved and quicker method and system to determine hydrologic conditions associated with a surface point.

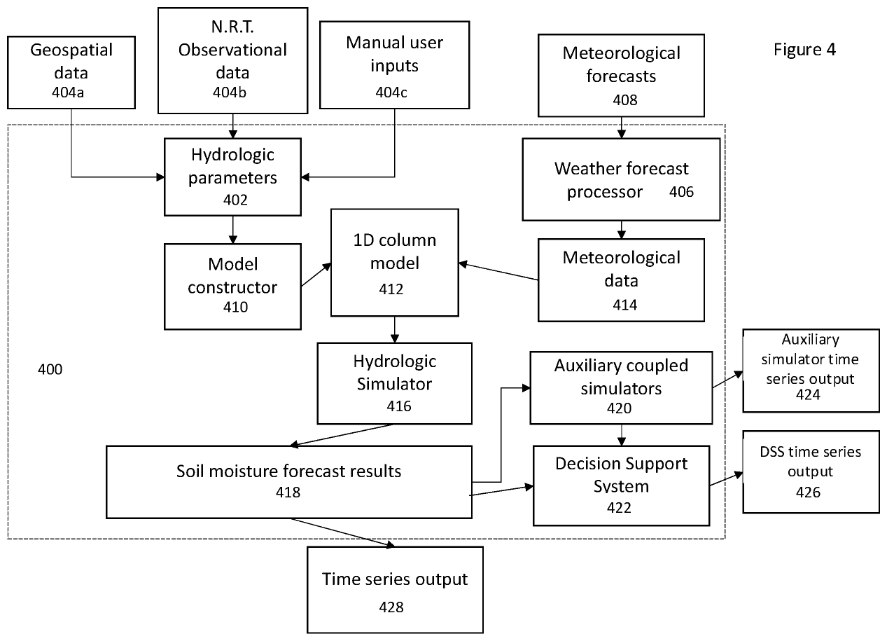

Turning to FIG. 4, a schematic diagram of one embodiment of a system of the disclosure in its environment is shown. In one embodiment, the system may be seen as a system for simulating and/or near real-time forecasting of future or historical hydrologic conditions associated with a surface point in a fully integrated 1D setting. In another embodiment, the system may provide future or historical re-analysis of shallow subsurface hydrology in a fully integrated 1D setting.

The system 400 includes a hydrologic parameters interface 402 that receives inputs from external information or data sources 404 such as, but not limited to, a geospatial data external source 404a, a near real-time (N.R.T.) observational data external source 404b and user inputs 404c. It will be understood that the external data sources in FIG. 4 are not meant to be an exhaustive list and that other external data sources may be contemplated. The system 400 further includes a weather forecast processor 406 that receives input, such as meteorological forecasts or other meteorological data, from a meteorological data external source 408. In the current embodiment, the system 400 further includes a model constructor 410 that is connected to the hydrologic parameters interface 402 and to a 1D column model generator 412. The 1D column model generator 412 also receives meteorological data 414 that has been processed by the weather forecast processor 406. In one embodiment, the manual user inputs 404c may include geographic location information and/or a depth of the 1D column so that the system can generate the 1D column to a desired depth. Alternatively, the model constructor 410 may default to a depth value between 1 and 5 m. The manual user inputs 404c may also include hydrologic settings for the generation of the 1D column by the 1D column model generator 412. For instance, the user inputs may provide an input to the column model constructor 410 relating to whether the 1D column represents a hillslope or topographic depression. These inputs along with the N.R.T. observational data 404b allow the model constructor 410 to specify or determine hydrologic boundary conditions on the 1D column model that is generated by the 1D column model generator 412. In some embodiments, the model constructer 410 and the 1D column model generator may be combined into a single component. The model constructor 410 also uses or processes the geospatial data inputs 404a to determine material properties such as, but not limited to, hydraulic conductivity or root presence at depths throughout the 1D column model generated by model generator 412.

An output of the 1D column generator 412 is connected to a hydrologic simulator 416 which generates soil moisture forecast, or historical, results 418 along with other soil conditions. The soil moisture results 418 may be in the form of the 1D column of FIG. 3. The soil moisture results 418 may be used by auxiliary coupled simulators 420 and a decision support system 422 to assist in determining hydrologic conditions so that users can make informed decisions with respect to area of interest. In one embodiment, an output of the auxiliary coupled simulators (ACS) 420 generates an ACS time series output 424 and an output of the decision support system (DSS) or DSS component 422 generates a DSS time series output 426. These outputs may be transmitted or delivered to an end user so that the end user can make the informed decision.

The soil moisture results 418 may also be used to generate a soil moisture forecast, or historical, time series output 428. The time series output may be a text or binary file containing predicted levels of physical quantities or rates at regular time intervals. These quantities might include the level of soil moisture at different depths, and soil moisture may be measured in terms of volumetric water content, hydraulic pressure head, or relative soil saturation.

The fully integrated hydrologic simulator 416 of FIG. 4 may, in one embodiment, take the form of a numerical model, a statistical model, a machine learning model, or any other form of simulation engine. The hydrologic simulator 416 may also be implemented as computer code or a computer code script that takes a parameterized hydrologic model and generates a prediction of the hydrologic state within the model domain at future times. In the form of a numerical model, the simulator 416 may involve the solution of partial differential equations such as Richards' Equation and Darcy's Law. In the form of a statistical model or machine-learning model, the simulator 416 may involve the inference of future conditions based on correlations derived from previous conditions, for instance using non-linear regression.

Although not specifically shown, the system of FIG. 4 may receive other inputs such as, but not limited to, a geographic coordinate pair defining a surface location, geospatial databases in vector format, geospatial databases in raster format, parameter look-up tables and/or manual user inputs that may be gathered through the hydrologic parameters interface 402; and gridded or point-scale meteorological data, in-situ sensor data, spaceborne satellite sensor data, and/or daily continental or global land surface model data received by the weather forecast processor 406.

Outputs from the system 400 may include one-dimensional hydrologic forecasts or scenario analyses in the form of time series predictions of hydrologic variables 428 or historical conditions of the hydrologic variables. The hydrologic variables in the output time series 428 may include soil moisture or hydraulic head information at different depths below ground level. Alternatively, the system may output a historical analysis of the soil or ground being represented by the 1D column.

Other system outputs 424 may include, but are not limited to, predictions of supplementary variables that may be dependent on soil moisture, such as crop growth, fire risk, ecosystem goods and services (EG&S) valuation. Additional outputs from the decision support system component 422 may include land management operation recommendations.

In some embodiments, the vertical, 1D model, or column, may be seen as a simplification of the flow of water through a fully three-dimensional (3D) environment (such as the water cycle representation of FIG. 1) which provides advantages over the larger 3D models.

One advantage is that the 1D model can have a reduced memory footprint and therefore requires less simulation, or processing, time and computational expense, allowing for on-the-fly, or dynamic, simulations. Another advantage is that by focusing solely on vertical fluxes and not horizontal flow, numerical boundary conditions are simplified, allowing for 1D models to be placed in a larger variety of locations. In other words, multiple 1D columns may be displayed or generated in a single representation. Also, the 1D column is more easily parameterized than a 3D model since there are fewer parameters required. This enables an end-user to specify soil types, vegetation type, and moisture conditions such as via the manual user inputs 404c (that are received by the hydrologic parameter interface 402) and can be processed by the model constructor 410. By having the hydrologic simulation engine, or hydrologic simulator 416, as a part of the system 400, a further advantage of the disclosure is provided over current agriculture technology tools that do not propagate soil moisture and root zone conditions forward through or backward in time. The simulation outputs provided by the system and method of the disclosure may enable improved operational decision making related to agricultural resources management and other near-surface hydrological applications or may provide insight into historical conditions.

Returning to FIG. 4, in operation, meteorological forecast inputs 408 to the system are received and processed by the weather forecast processor 406. In one embodiment, the weather forecast processor 406 may extract a time series of meteorological variables and/or generate sequences of physical quantities or rates or meteorological variables at regular time intervals.

The meteorological variables of interest may include liquid precipitation, snowmelt, and potential evapotranspiration at the user-specific surface point at a moment in time or over a specific time period. In one embodiment, the meteorological forecast data 408 may be in the form of gridded weather forecasts, or point-scale weather forecasts, or it might be a gridded reanalysis dataset. The meteorological data may be stored as time series data in a text or binary file, or it may be stored in a database, either internal to the system or remote from the system, and retrieved by the system or transmitted from the database to the system 400. The meteorological time series data may span different time periods, such as, but not limited to, an 18 hour time period, a two-week time period, a one month time period or a six month time period. Typically, the selected time period is one week. For some applications, the meteorological data may include re-analysis data, which may be seen as archived and corrected meteorological data that may provide guidance for a historical review of past hydrological conditions with respect to the area of interest. If the meteorological data is gridded (such as in a raster format), a geospatial query is applied to extract a time series of meteorological forecast data at the point of interest.

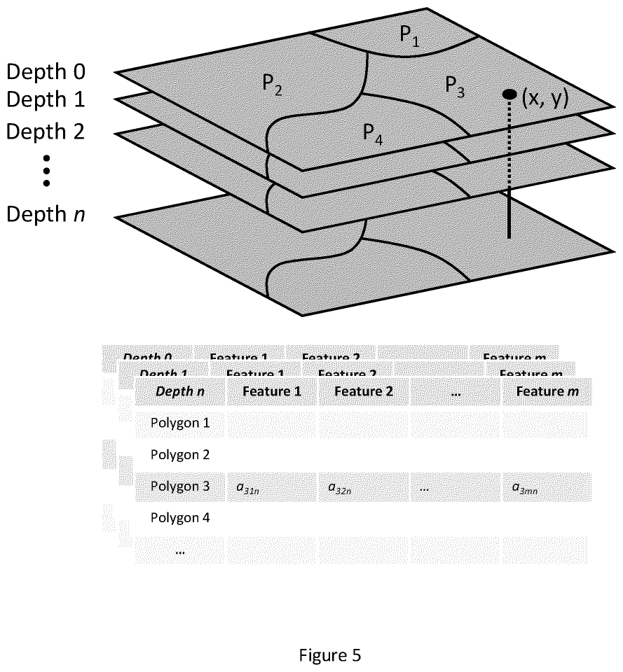

The system depicted in FIG. 4 further includes inputs to parameterize the 1D model. As discussed above, these inputs might be any combination of geospatial databases, near-real-time observational data, or manual user inputs. Geospatial data, such as schematically depicted in FIG. 5, may include soils databases, land cover mapping datasets, topographic datasets such as digital elevation models, regional hydrogeologic flow maps, and geological or hydrostratigraphic maps.

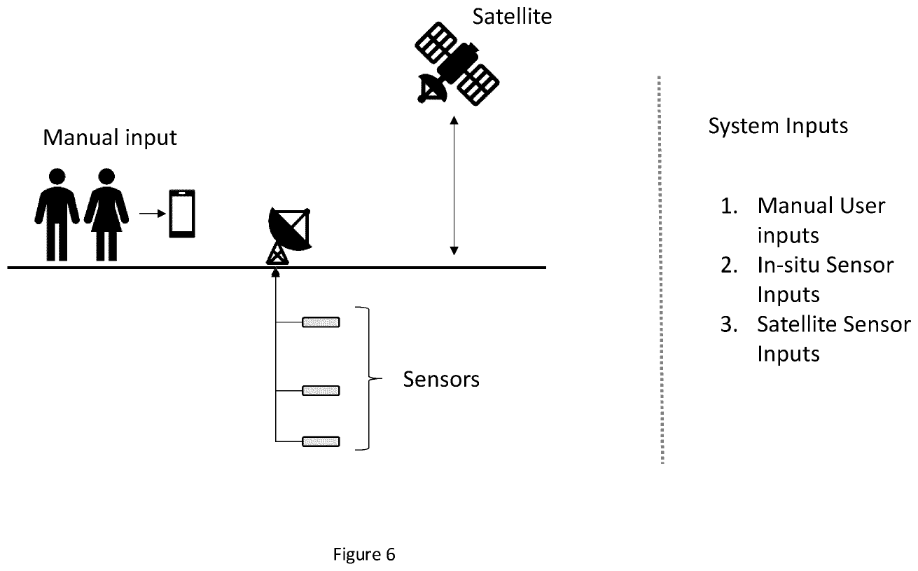

In operation, or use, geospatial input 404a may be in the form of a geospatial query 404a (such as the one shown in FIG. 5) that is used to extract parameter values relating to the land underneath the surface point at various depths. When the geospatial dataset extends over multiple depths, a weighted averaging may be performed to determine hydrostratigraphic properties for each depth (or section) in the column model (as schematically shown in FIG. 3). The N.R.T. observational data inputs 404b, such as schematically depicted in FIG. 6, may include time series feeds of soil sensor data which may include variables such as, but not limited to, soil moisture and temperature at various depths. Other near real-time observational data may include remote sensing imagery or remote sensing derived products such as soil moisture imagery, soil temperature imagery, or vegetation growth indices. Examples of vegetation growth indices include a normalized difference vegetation index (NDVI) or a leaf area index (LAI). Manual user inputs 404c may include the geographic coordinates of an area or point of interest, information about soil moisture content, information about irrigation schedules, information about crop growth status, or information about local soil characteristics.

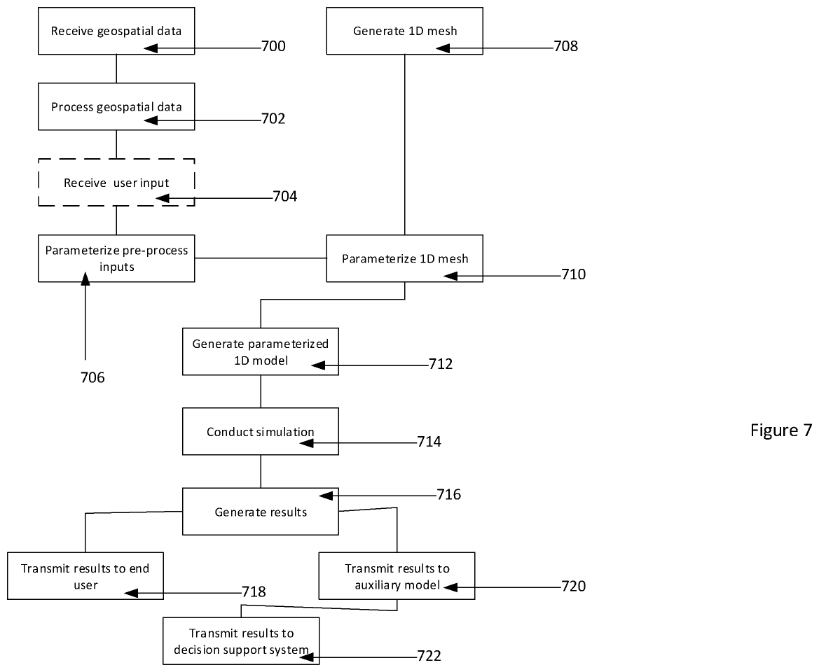

Turning to FIG. 7, a flowchart outlining a method for determining hydrologic conditions for a surface point in a 1D setting is shown. More specifically, the flowchart of FIG. 7 may be seen as providing a method for simulation future or historical hydrologic conditions of shallow subsurface hydrologic flows through soil and bedrock represented as vertical 1D hydrostratigraphic columns. The method may also be used to generate a representation of historical subsurface hydrologic information for a surface point.

Initially, geospatial data may be input into and received or retrieved (700) by the system and processed (702) such as via a spatial query. In one embodiment, the spatial query may include the sampling of a two-dimensional (2D) surface or a 3D volume at a point location within the geospatial data. In one embodiment, this may be the surface point of FIG. 2. In some embodiments, the system may further receive user input data (704) such as, but not limited to, information about soil type, crop type, or land cover type. The inputs (either the spatially queried geospatial data or the combination of the spatially queried geospatial data and the user input data) are then further processed, such as via a parameter pre-processing (706) to convert the inputs into valid parameter values. Valid parameters may include, but are not limited to, saturated hydraulic conductivity, soil saturation curve parameters, root depths, plant water uptake rates, soil porosity, ground surface friction, and/or leaf area index. In one embodiment, specification of these parameters may be required to constrain the flow solution and to enable valid simulation results. The parameter pre-processing (706) may include the use of parameter lookup tables, or the use of soil pedotransfer functions. The soil pedotransfer functions may include aspects of machine learning. In some embodiments, the user inputs are stored as hydrologic parameters in a database or text/binary file and then transmitted to or fed into a processor for pre-processing, when needed.

Concurrently, a 1D model mesh may be generated (708) whereby the 1D model mesh may then be combined with the pre-processed information to parameterize the 1D model mesh (710).

A parameterized 1D model, which may also be seen as a discretized column model mesh, is then generated (712). In one embodiment, the model constructor and/or the model generator 412 (as shown in FIG. 4) generates the discretized 1D column model mesh based on the parameterized 1D model mesh, initial state information (such as supplied via observational data) and meteorological data, which may or may not be processed via a spatial query.

Based on the parameterized 1D model, the system, such as via the model constructor component, may then sample the hydrologic parameter values at each discrete point on the mesh to conduct a simulation, or analysis, (714) which results in the generation of a set of results (716) which may be forecasting/simulation or historical analysis results.

As schematically shown in FIG. 4, the hydrologic simulator component 416 (performing the simulation in (714) may determine or generate either a single deterministic forecast, or a probabilistic forecast including an ensemble of individual forecasts that produce a probability distribution.

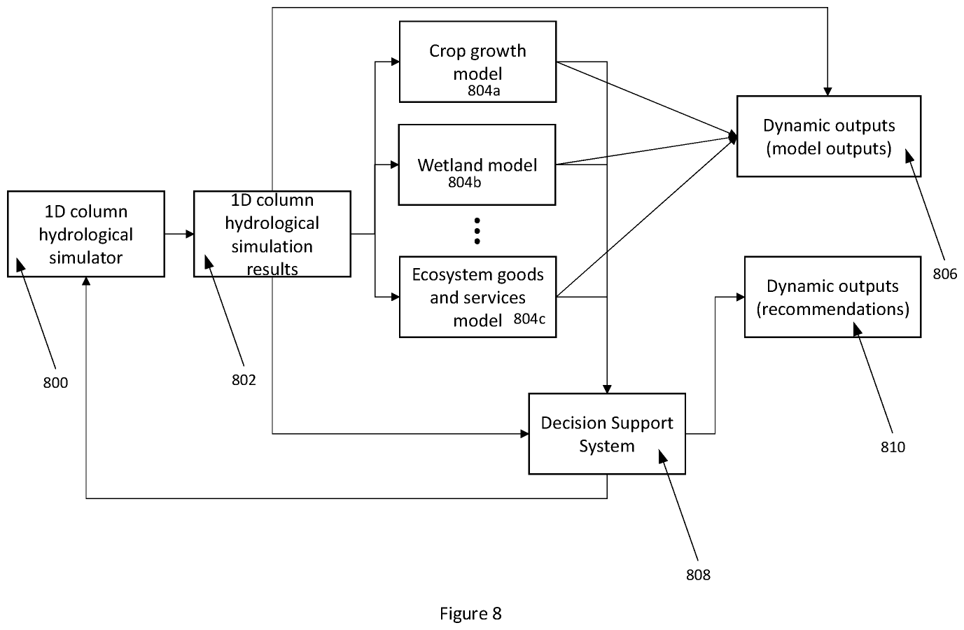

The outputs (or results) from the hydrologic simulator computer as generated in (716) may include time series predictions of state variables at different depths. In some embodiments, the results may be delivered or transmitted directly to an end-user (718) through a graphical web interface or application programming interface. Alternatively, the results might be transmitted to a coupled auxiliary model (720) (the ACS), which might provide the functionality for modeling vegetation growth, fire risk, contaminant transport, heat transport, or ecosystem goods and services (EG&S) valuations. Further examples of auxiliary models are discussed in FIG. 8. Outputs from the auxiliary models may also include time series predictions at various depths. The outputs from the auxiliary simulator may be passed to an end-user through a graphical interface or API. Alternatively, the outputs from either or both of the hydrologic and auxiliary simulators or models may be passed to the decision support system (722), which may implement methods from operations research to inform optimal or near-optimal operational practices to meet a user-specified goal, such as maximizing or improving crop growth given limited irrigation water supply. Again, the outputs from the decision support system may include a time series of recommended operational actions, or decision variables. The passing of decision variable outputs and simulator outputs may be cyclical, as depicted in FIG. 8.

As shown in FIG. 8, the 1D hydrological simulator 800 generates a set of 1D column hydrological simulation results 802, such as in a manner discussed above. The simulation results 802 may then be transmitted to different models 804 or auxiliary models, such as, but not limited to, a crop growth model 804a, a wetland model 804b and/or an ecosystem goods and services model 804c. By passing the results through these models, further information or data may be generated which may be seen as dynamic outputs or model outputs 806. The dynamic outputs 806 may also include the simulation results 802. The simulation results 802 and the outputs of the models 804 may also be passed to a decision support system 808 which may then use the inputs to make decisions or determine historical and/or future soil conditions or to make recommendations. An output or multiple outputs of the decision support system 808 may be seen as dynamic outputs 810 or recommendations. Output or outputs of the decision support system 808 may also be transmitted back to the simulator 800 to perform updated simulations with more recent data.

In one embodiment, the disclosure may be implemented and executed as software on the cloud (e.g., Microsoft Azure or Amazon Web Services) or local computing resources and connected to a web-based graphical user interface that enables users to interact with the system. The system may receive user inputs via the graphical user interface and use the same interface to present results back to the user. Results may also be delivered or transmitted to end-users through application programming interfaces (APIs). User inputs or soil sensor networks may also be implemented via computer software on mobile computing devices, and they might be connected to the cloud through an edge computing interface.

One advantage of the disclosure is that whereas large basin-scale fully integrated hydrologic models can be highly sensitive to initial conditions, there is more flexibility using a 1D setting or model, since the numerical complexity of the problem is reduced. With a 1D column or model, the user may be able to specify valid hydraulic head distributions within the column based off of a single point observation of soil moisture or a qualitative description of soil wetness.

In some embodiments, the model constructor component may also specify boundary conditions and/or model initial conditions for the simulation or re-analysis. An initial condition may be defined as the model state at the beginning of the simulation and a boundary condition may be defined as any hydraulic pressure or pressure gradient on the boundaries of the model domain.

Determination of the model initial conditions may include an extrapolation or interpolation of observed and/or specified soil moisture values. As schematically shown in FIG. 6, the observed soil moisture values may be taken from point soil moisture sensors, or they may be sampled from a remote sensing soil moisture product, such as, but not limited to, a SMOS L3/L4 soil moisture dataset. In the absence of observed or specified soil moisture data, initial soil moisture conditions may be sampled from a continental-scale land surface model reanalysis product or from a basin scale hydrogeologic forecasting model. In one configuration, geostatistical interpolation may be applied.

Subsurface boundary conditions may be set to either a no-flow condition, a drain-type boundary, or either a specified head or specified flux boundary. The choice of boundary condition selected by the model constructor depends on the regional hydrostratigraphy and regional groundwater flow patterns, which may be obtained through a geospatial query on various map datasets.

FIG. 3 depicts a one-dimensional column model, and in this example there might be specific parameter values specified for each of the rectangular prism elements or vertices (nodes).

In one embodiment, one advantage, or functionality, of the current disclosure is the ability to run a simulation in any geographic location and be able to change model parameters on-the-fly to evaluate different land management practices.

In some specific embodiments, the disclosure system may involve driving columnar, one-dimensional hydrogeologic models at individual geographic coordinate pairs with meteorologic forecasts that might span a predetermined timeframe range. One example of a predetermined timeframe range may be 18 hours to 32 days. This may generate a timed series of soil moisture predictions or representations at different depths within the soil root zone. For example, in one embodiment, the interval of the time series of predictions may be hourly or daily. These time series predictions may be coupled to a DSS that delivers insights to managers of farms, forests, and other ecosystems. One embodiment of a DSS might include a crop growth model or a risk model.

In another embodiment, the disclosure is directed at a method and system for simulation and near real-time forecasting of shallow subsurface hydrologic flows or historical shallow subsurface hydrologic flows through soil and bedrock represented as vertical one-dimensional hydrostratigraphic columns.

In another embodiment, the disclosure may include the automated construction of 1D column models. One specific method involves a geospatial query on one or more public-domain map datasets, which may contain information about soil types, land use, vegetation type, or topography. An intermediate pre-processing step may involve the application of soil pedotransfer functions and parameter lookup tables to parameterize the column models. The model construction may also involve gathering inputs from end-users, to configure custom material properties or land management practices.

In a further embodiment, the disclosure includes the automated querying of meteorological forecast data, which may be used to drive the column simulator. Also considered is the incorporation or assimilation of near-real-time state variable data which might include observational data derived from soil sensors or spaceborne sensors, or which might be derived from daily global analysis datasets, or which might involve user inputs.

Although the present disclosure has been illustrated and described herein with reference to preferred embodiments and specific examples thereof, it will be readily apparent to those of ordinary skill in the art that other embodiments and examples may perform similar functions and/or achieve like results. All such equivalent embodiments and examples are within the spirit and scope of the present disclosure.

In the preceding description, for purposes of explanation, numerous details are set forth in order to provide a thorough understanding of the embodiments. However, it will be apparent to one skilled in the art that these specific details may not be required. In other instances, well-known structures may be shown in block diagram form in order not to obscure the understanding. For example, specific details are not provided as to whether elements of the embodiments described herein are implemented as a software routine, hardware circuit, firmware, or a combination thereof.

Embodiments of the disclosure or components thereof can be provided as or represented as a computer program product stored in a machine-readable medium (also referred to as a computer-readable medium, a processor-readable medium, or a computer usable medium having a computer-readable program code embodied therein). The machine-readable medium can be any suitable tangible, non-transitory medium, including magnetic, optical, or electrical storage medium including a diskette, compact disk read only memory (CD-ROM), memory device (volatile or non-volatile), or similar storage mechanism. The machine-readable medium can contain various sets of instructions, code sequences, configuration information, or other data, which, when executed, cause a processor or controller to perform steps in a method according to an embodiment of the disclosure. Those of ordinary skill in the art will appreciate that other instructions and operations necessary to implement the described implementations can also be stored on the machine-readable medium. The instructions stored on the machine-readable medium can be executed by a processor, controller or other suitable processing device, and can interface with circuitry to perform the described tasks.

What is claimed is:

1. A method of determining hydrologic conditions associated with a surface point comprising:
generating a one-dimensional (1D) mesh based on inputs associated with the surface point;
parameterizing the 1D mesh; and
generating a parameterized 1D model for use in determining the hydrologic conditions of soil associated with the surface point.

2. The method of claim 1 wherein the hydrologic conditions are associated with historical conditions of the soil associated with the surface point or a simulation of future conditions of the soil associated with the surface point.

3. The method of claim 1 further comprising:
performing at least one simulation on the parameterized 1D model to generate simulation results.

4. The method of claim 3 further comprising:
transmitting the simulation results to an auxiliary model to generate auxiliary model results.

5. The method of claim 4 further comprising:
transmitting the auxiliary model results to a decisions support system.

6. The method of claim 4 wherein the auxiliary model comprises at least one of a crop growth model, a wetland model or an ecosystem goods and services model.

7. The method of claim 1 wherein parameterizing the 1D mesh comprises:
processing geospatial data;
parameterizing the processed geospatial data; and
combining the parameterized processed geospatial data with the 1D mesh.

8. The method of claim 1 further comprising:
processing user inputs;
parameterizing the user inputs; and
combining the parameterized user inputs with the 1D mesh.

9. The method of claim 1 wherein the inputs comprise at least one of geospatial data, near real-time observational data or meteorological data.

10. A system for determining hydrology conditions associated with a surface point comprising:
an interface for receiving inputs; and
a one-dimensional model constructor for processing the inputs and for generating a 1D model presenting hydrology properties associated with the surface point.

11. The system of claim 10 wherein the inputs comprise geospatial data; near real time observational data; manual user inputs or meteorological data.

12. The system of claim 10 further comprising:
a hydrologic simulator for generating hydrology simulation results based on the 1D model.

13. The system of claim 12 wherein the hydrology simulation results comprise historical conditions of the soil associated with the surface point or a simulation of future conditions of the soil associated with the surface point.

14. The system of claim 12 further comprising a set of auxiliary models for generating auxiliary outputs based on the simulation hydrology results.

15. The system of claim 12 further comprising a decision support service component.
